(19) United States
(12) Patent Application Publication
(10) Pub. No.: US 2007/0034927 A1
(43) Pub. Date: Feb. 15, 2007

(54) Trench storage capacitor

(76) Inventors: Harald Seidl, Poring (DE); Dirk Manger, Dresden (DE); Matthias Goldbach, Dresden (DE); Albert Birner, Dresden (DE); Stefan Slesazeck, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/272,038

(22) Filed: Nov. 14, 2005

Related U.S. Application Data
(63) Continuation of application No. PCT/DE04/01003, filed on May 13, 2004.

(30) Foreign Application Priority Data
May 13, 2003 (DE) 103 21 466.6

(51) Int. Cl. H01L 29/94

(52) U.S. Cl. 257/301

(57) ABSTRACT

A trench storage capacitor includes a buried plate that is lengthened by a doped silicon layer to right over the collar insulating layer. The conductor layer of the trench storage capacitor is preferably applied to a “buried” collar insulating layer and masked with the aid of a protective layer fabricated by ALD. In an exemplary embodiment, the conductor layer is composed of amorphous silicon, which is used as an HSG layer in a lower trench region.

### CROSS REFERENCE TO RELATED APPLICATIONS

This application is a continuation of International Application No. PCT/DE2004/001003, filed on May 13, 2004, and titled “Trench Memory Capacitor and Method For Producing the Same,” and further claims priority under 35 USC §119 to German Application No. 103 21 466.6, filed on May 13, 2003, and titled “Trench Storage Capacitor and Method For Fabricating It,” the entire contents of which are hereby incorporated by reference.

### FIELD OF THE INVENTION

The present invention relates to trench storage capacitors and methods of forming trench storage capacitors.

### BACKGROUND

In memory cells having a storage capacitor and a selection transistor, such as in the case of a DRAM, for example, a buried plate made of doped semiconductor material of a semiconductor body is situated as a bottom electrode in a lower trench region of a DT (DT=deep trench), while an upper trench region, as collar part, is provided with an insulating layer that electrically isolates the storage capacitor, namely the buried plate, from the selection transistor. The consequence of this is that the entire area of the collar part cannot be utilized as capacitor area. By way of example, if the collar part in the case of a storage capacitor takes up a depth of approximately 1.5 μm in the case of a total depth of the DT of approximately 8 μm, then this means that approximately 20% of the area of the trench is lost for the storage capacitor and the latter has a correspondingly lower capacitance.

### SUMMARY OF THE INVENTION

It is an object of the present invention to provide a trench storage capacitor in which the collar part of the trench is also utilized for the capacitance of the storage capacitor.

It is another object of the present invention to provide a method for fabricating such a storage capacitor.

The aforesaid objects are achieved individually and/or in combination, and it is not intended that the present invention be construed as requiring two or more of the objects to be combined unless expressly required by the claims attached hereto.

In accordance with the invention, a trench storage capacitor includes a collar part located in an upper trench region that is utilized as capacitor area. The buried plate is thus “lengthened” into the collar part. This is done with the aid of a conductor layer made preferably of amorphous or polycrystalline silicon. The conductor layer is formed after the fabrication of the collar.

Problems with integrating the collar part into the capacitance of the storage capacitor by “lengthening” the buried plate by the conductor layer are the geometrical boundary conditions given in the upper trench region. As the dimensions become smaller and smaller, less and less space is available in the collar part, too. This small space is further limited by the conductor layer, even with a thin embodiment, thereby additionally aggravating the problem area mentioned.

However, since the collar is preferably “buried” in the sidewall of the trench, the thin conductor layer can be formed by deposition of silicon and subsequent doping thereof and ALD (ALD=atomic layer deposition) of aluminum oxide, for example, as a protective layer is performed for the patterning of the conductor layer, the geometrical boundary conditions given can be complied with.

In order to increase the capacitance, an HSG layer (HSG=hemispherical grain) may additionally be provided in an advantageous manner between the dielectric layer of the capacitor and the buried plate thereof. The HSG layer may be fabricated together with the conductor layer in the collar part for example from an amorphous silicon layer.

What is essential to the trench storage capacitor according to the invention is the “lengthening” of the buried plate in the collar part, so that the upper trench region can also be utilized as capacitor area, as a result of which the capacitance of the storage capacitor can be increased by at least approximately 10% to 20%.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIGS. 1 to 9 show sectional views through a semiconductor body with a trench in different forming stages in accordance with a first exemplary embodiment of the invention.

FIGS. 10 to 12 show sectional views through a semiconductor body with a trench in different forming stages in accordance with a second exemplary embodiment of the invention.

### DETAILED DESCRIPTION

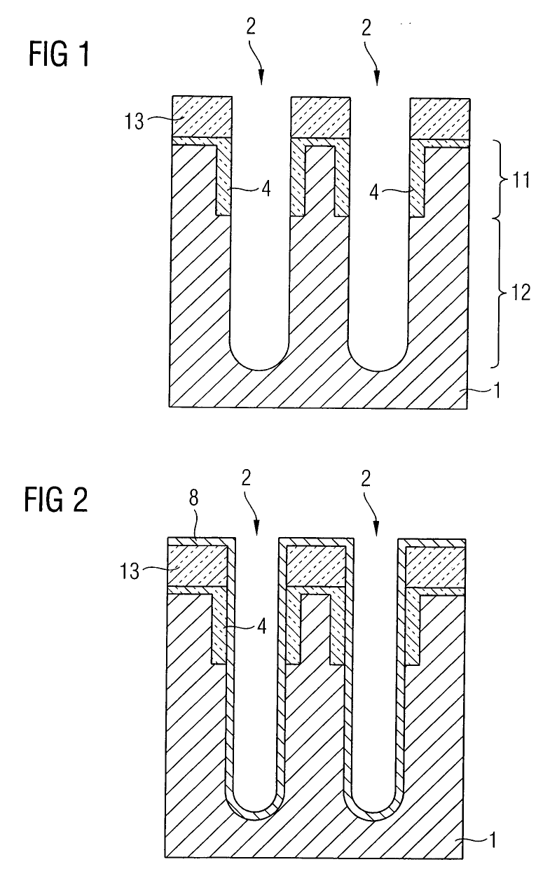

FIG. 1 shows a semiconductor body 1 made, for example, of silicon with trenches 2, which have an upper trench region 11 and a lower trench region 12 and thus form DTs. Collar insulating layers 4 made, for example, of silicon dioxide and/or silicon nitride are situated in the upper trench region 11. The collar insulating layers are buried in the sidewall of the trench 2. They may be fabricated for example by CFE (CFE=collar formation during etch or collar formation during the trench etching process).

Other materials may also be used instead of the materials specified. Thus, instead of silicon for the semiconductor body, it is also possible to choose another suitable semiconductor material, such as, for example, silicon carbide, compound semiconductor, etc. The semiconductor body itself may be p-doped, for example. However, other dopings are also possible. In general, the conduction types respectively specified may also be reversed.

The arrangement obtained after trench etching with the aid of an etching mask 13 made, for example, of silicon nitride and collar formation of the collar insulating layer 4 is shown in FIG. 1.

This is then followed by the deposition of a thin conductor layer 8, having a thickness of approximately 5 to 30 nm and preferably 10 to 20 nm, in the trench 2 and on the surface of the arrangement of FIG. 1. Undoped silicon is preferably used for the conductor layer 8.

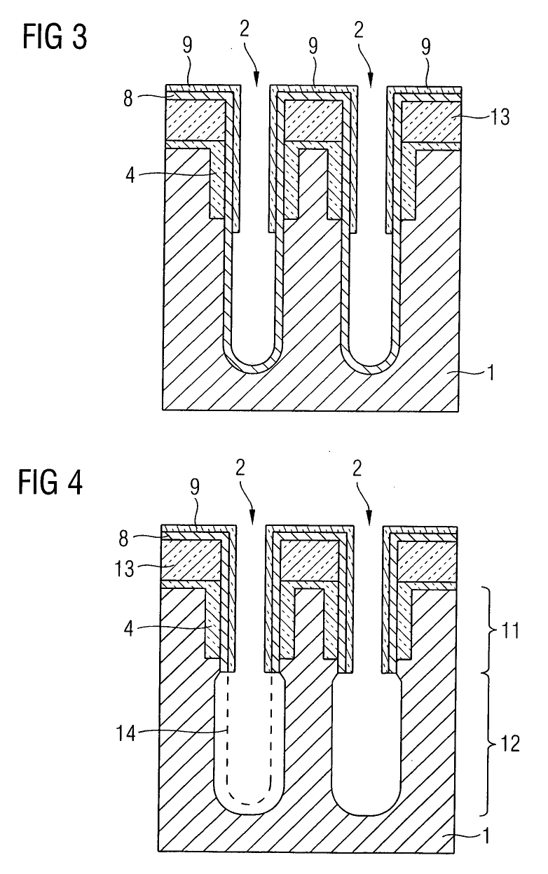

Instead of silicon, another material, such as metal, for example, may also be used, if appropriate, for the conductor layer 8. However, this other material should be selectively etchable with respect to a protective layer 9 that is to be applied later (described below and depicted in FIG. 3).

In any event, the arrangement shown in FIG. 2 is finally obtained in this way, in which arrangement the conductor layer 8 is applied to the surface of the arrangement of FIG. 1.

It should be noted that the collar insulating layer 4 made of silicon nitride, for example, which forms the collar part also extends over the surface of the semiconductor body 1. This need not necessarily be the case, however. It suffices for the insulating layer 4 to be present in the upper trench region 11.

This is then followed by a nonconformal deposition of aluminum oxide (Al₂O₃), for example, by ALD, the protective layer 9 thus formed extending as far as a depth below the lower edge of the collar insulating layer 4 as shown in FIG. 3. By way of example, TMA (trimethylaluminum) together with water (H₂O) may be used for this deposition, in which case the layer thickness of the protective layer 9 may be approximately 5 to 10 nm. Instead of aluminum oxide, other materials may also be used for the protective layer 9 provided that they are selectively etchable with respect to the conductor layer 8.

The arrangement shown in FIG. 3 is thus finally present, which arrangement also contains the protective layer 9 in addition to the arrangement of FIG. 2 in the upper trench region 11 and somewhat beyond to below the lower edge of the collar insulating layer 4.

This may then optionally be followed by a heat treatment of the protective layer 9 made, in particular, of aluminum oxide at approximately 600° C. to 1200° C., in particular 800° C. to 1000° C., for a time duration of 10 seconds to 100 seconds, in order thus to “densify” the protective layer. However, this optional step may also be omitted, if appropriate.

A “wet bottle” process (wet-etching process) then follows, in which the conductor layer 8 made, preferably, of silicon which is not covered by the protective layer 9, that is to say essentially the conductor layer 8 in the lower trench region 12, is removed. If appropriate, the crystalline silicon of the semiconductor body 1 may additionally be etched as well in the process in order to increase the diameter of the trench 2 in the lower trench region 12. The protective layer 9 prevents etching of the conductor layer 8 in the upper trench region 11.

The arrangement shown in FIG. 4 is formed from the “wet bottle” process, in which arrangement the lower trench region 12 is extended and has a larger diameter than the upper trench region 11. This extension is not mandatory, however. Rather, the lower trench region may have the same diameter as the upper trench region. In other words, etching of the crystalline silicon of the semiconductor body 1 does not have to take place. In this case, the lower trench region 12 retains the form indicated by a broken line 14 shown in FIG. 4.

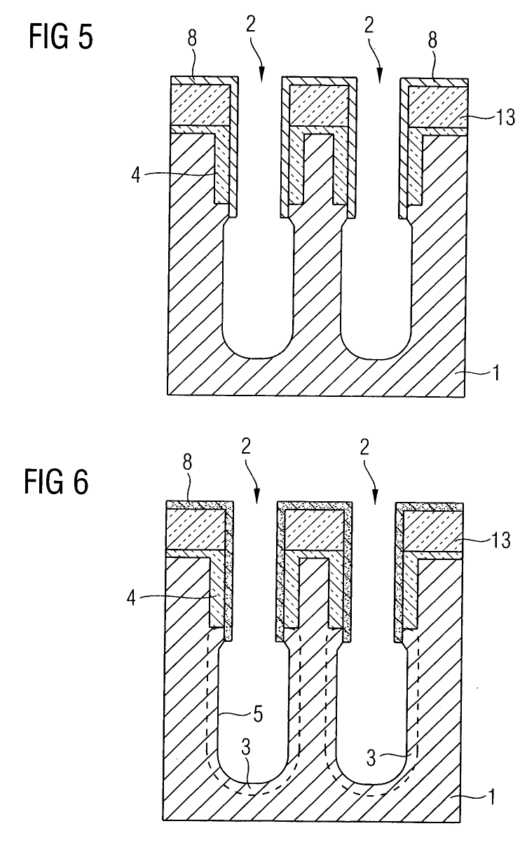

The protective layer 9 is subsequently removed. If the protective layer comprises aluminum oxide, for example, then this may be done by etching with a suitable acid. The arrangement shown in FIG. 5 is formed upon removal of the protective layer 9.

A buried plate 3 is subsequently introduced into the trench wall 5 in the lower trench region 12 as shown in FIG. 6. This may be done by gas phase doping. A suitable process for forming the buried plate is providing an AsH₃ atmosphere at a temperature of approximately 950° C. The buried plate 3 is produced in this way, and at the same time the conductor layer 8 made of silicon is likewise doped with arsenic.

Instead of arsenic, it is also possible to use another suitable dopant, such as phosphorus or antimony, for example, for an n-type doping. If a p-type doping is to be performed, then boron, for example, could be used.

The arrangement shown in FIG. 6 thus includes the buried plate 3, and the conductor layer 8 made of silicon is doped with arsenic. The layer 8, which has previously been referred to as a conductor layer even though it comprises undoped amorphous or polycrystalline silicon, becomes a conductor layer and exhibits good conductor properties once it has been doped with arsenic (or another suitable dopant).

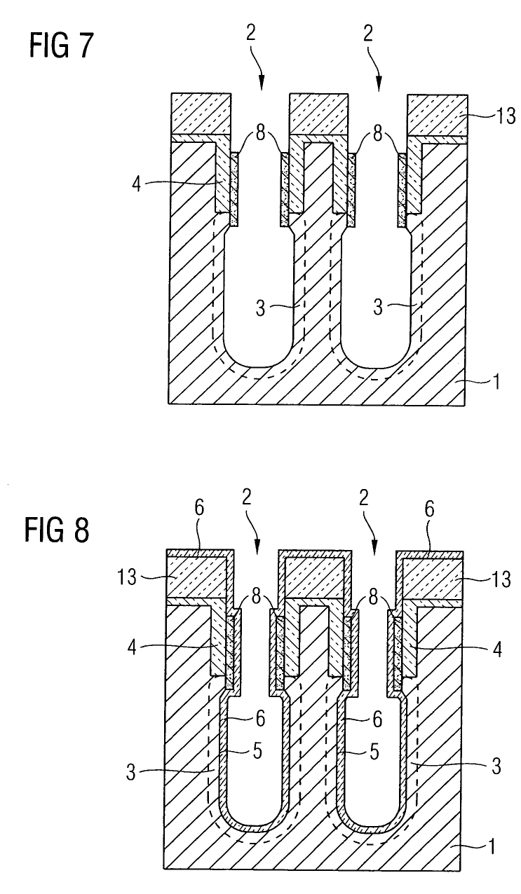

The doped layer 8 is then etched back in the upper trench region, so that it remains only in the region of the collar. The arrangement shown in FIG. 7 is thus produced.

A node dielectric made, for example, of NO or aluminum oxide is subsequently deposited in order to form a dielectric layer 6 in the interior of the trench on the trench wall 5 and on the surface of the arrangement. A suitable material, such as, for example, silicon dioxide and/or silicon nitride, may also be used for the dielectric layer 6. The arrangement shown in FIG. 8 is thus obtained.

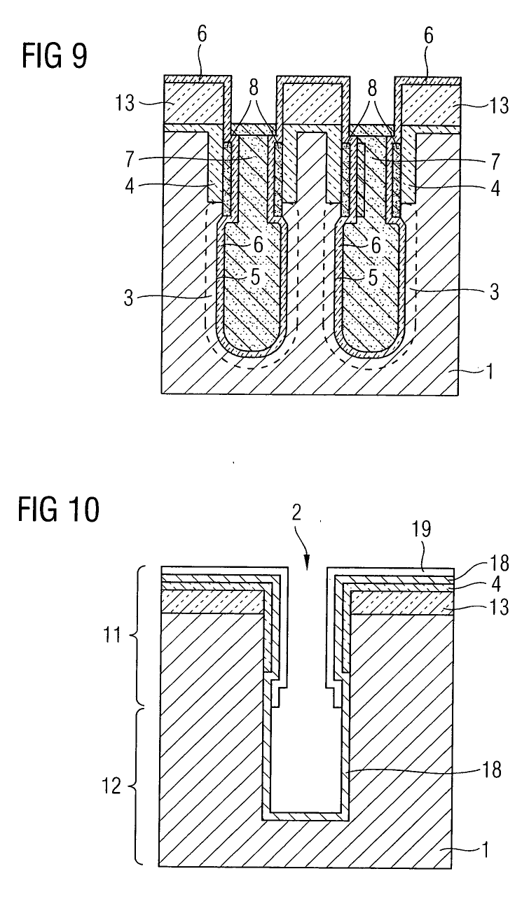

This is then followed by a deposition of a trench filling 7 forming a counterelectrode in the interior of the trenches 2 and etching-back of the trench filling in the upper trench region 11. Doped polycrystalline silicon is preferably used for the trench filling 7. A suitable dopant for this is arsenic, for example. The arrangement shown in FIG. 9 is thus formed.

Instead of polycrystalline silicon, another suitable metallically conducting material may also be used for the trench filling 7. However, polycrystalline silicon is preferably used.

In the arrangement shown in FIG. 9, the trench plate 3 is “lengthened” by the residual conductor layer 8 made of doped silicon right into the upper trench region 11 on the collar insulating layer 4. The capacitance increase thus obtained amounts to approximately 10 to 20% of the original capacitance without the conductor layer 8.

The arrangement of FIG. 9 thus shows a storage capacitor with the buried plate 3 and the conductor layer 8 as bottom electrode and the trench filling 7 as counterelectrode. The dielectric layer 6 lies between the two electrodes. This storage capacitor may then be connected to a selection transistor in a customary manner in order thus finally to form a memory cell of a DRAM, for example.

FIGS. 10 to 12 show sectional views through a semiconductor body 1 in accordance with a further exemplary embodiment of the invention. In this exemplary embodiment, in contrast to the exemplary embodiment of FIGS. 1 to 9, an HSG layer 18 is additionally provided between the dielectric layer 6 of the capacitor and the buried plate 3 thereof. The HSG layer 18 increases the “area” of the capacitor and thus contributes to increasing its capacitance.

In the exemplary embodiment of FIGS. 10 to 12, a trench 2 is first introduced into the semiconductor body 1 by etching (FIG. 10). A masking layer 13 made, for example, of silicon dioxide is used as a mask. Afterward, a collar insulating layer 4 made, for example, of silicon dioxide is produced by nonconformal deposition in an upper trench region 11. Aluminum oxide may also be used, for example, instead of silicon dioxide. A layer 18 made of amorphous silicon is then deposited conformally in the trench 2. The layer 18 serves as an “HSG starter.” A liner layer 19 made of silicon nitride and/or silicon dioxide is formed nonconformally in the upper trench region 11. The lower trench region 12 is not covered by the layer 19. The structure shown in FIG. 10 is thus formed.

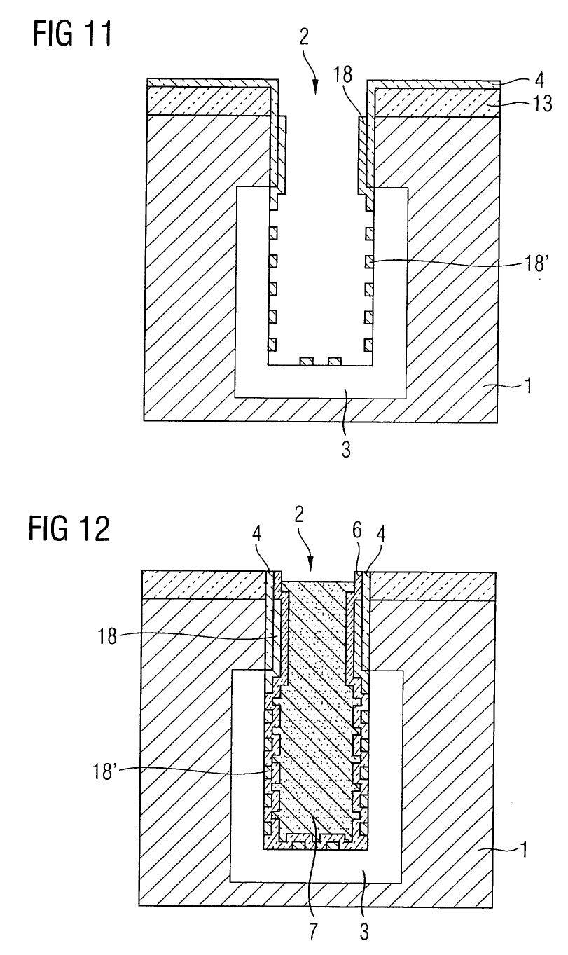

The layer 18 is subsequently converted into an HSG layer 18′ in a customary manner in its lower trench region 12 not covered by the layer 19. This may be done by etching, for example. The layer 19 is then removed, and a diffusion is performed in order to produce the buried plate 3 of the capacitor. Finally, the layer 18 is removed in the upper trench region 11 by dry etching. As a result, the structure shown in FIG. 11 is produced.

A dielectric layer 6 is then formed in the interior of the trench 2 on the surfaces of the layer 18, the HSG layer 18′ and the buried plate 3 as a “node dielectric.” A trench filling 7 made of doped polycrystalline silicon is subsequently introduced into the interior of the trench 2. The trench filling 7 is treated and etched back in a customary manner, with the result that the structure shown in FIG. 12 is formed. The way in which the layer 18 is connected to the buried plate 3 and thus lengthens the bottom electrode of the capacitor into the collar region 11 can clearly be seen here.

In the case of the exemplary embodiment of FIGS. 10 to 12, instead of the amorphous silicon for the layer 18, if appropriate, this layer may also be made of polycrystalline silicon or else a metal layer as shielding in the collar region 11 on the protective layer 4.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Semiconductor body
2 Trench
3 Buried Plate
4 Collar insulating layer
5 Trench wall
6 Dielectric layer
7 Trench filling
8 Conductor layer
9 Protective layer
11 Upper trench region
12 Lower trench region
13 Masking layer
18 Amorphous silicon layer
18′ HSG layer
19 Insulating layer

What is claimed:

1. A trench storage capacitor comprising:
a trench formed in a semiconductor body and including an upper trench region and a lower trench region, the upper trench region including a collar part;
a buried plate comprising a bottom electrode formed of doped semiconductor material of the semiconductor body in a region surrounding the lower trench region;
a collar insulating layer surrounding the collar part;
a dielectric layer that lines the trench wall in the lower trench region and is arranged in the lower trench region on the buried plate and further extends into the collar part at the upper trench region;
a trench filling forming a counterelectrode in the lower trench region and in the collar part; and
a conductor layer that is connected to the buried plate and is disposed in the collar part between the collar insulating layer and the dielectric layer.

2. The trench storage capacitor of claim 1, wherein the conductor layer disposed in the collar part comprises amorphous or polycrystalline silicon.

3. The trench storage capacitor of claim 2, wherein the amorphous or polycrystalline silicon of the conductor layer disposed in the collar part is doped.

4. The trench storage capacitor of claim 1, wherein the dielectric layer comprises at least one of silicon nitride, silicon dioxide, and aluminum oxide.

5. The trench storage capacitor of claim 1, wherein the trench filling forming the counterelectrode comprises doped polycrystalline silicon.

6. The trench storage capacitor of claim 1, wherein the buried plate is n-doped.

7. The trench storage capacitor of claim 6, wherein the dopant of the buried plate is arsenic.

8. The trench storage capacitor of claim 1, wherein the collar insulating layer comprises at least one of silicon dioxide and silicon nitride.

9. The trench storage capacitor of claim 1, wherein the conductor layer disposed in the collar part has a layer thickness of approximately 5 nm to 30 nm.

10. The trench storage capacitor of claim 9, wherein the conductor layer has a layer thickness of 10 nm to 20 nm.

11. The trench storage capacitor of claim 1, wherein the lower trench region forms a bottle part of the trench.

12. The trench storage capacitor of claim 11, wherein the bottle part has a larger diameter than the collar part.

13. The trench storage capacitor of claim 1, wherein the collar insulating layer is buried in a trench wall.

14. The trench storage capacitor of claim 1, wherein an HSG layer is provided between the dielectric layer and the buried plate.

15. The trench storage capacitor of claim 14, wherein the HSG layer and the conductor layer are formed from the same material.

16. A method for fabricating a trench storage capacitor comprising:
(a) fabricating a collar insulating layer in an upper trench region of a trench that is formed within a semiconductor body;
(b) depositing a thin conductor layer at least in the trench;
(c) depositing a thin protective layer into the trench as far as a selected depth below a lower edge of the collar insulating layer;
(d) removing at least part of the thin conductor layer in a lower trench region and in an area where the thin conductor layer is not covered by the protective layer;
(e) removing the protective layer;
(f) forming a buried plate in the lower trench region;
(g) etching-back a portion of the thin conductor layer in the upper trench region;
(h) depositing a dielectric layer at least in the trench; and
(i) depositing a trench filling as a counterelectrode in the trench.

17. The method of claim 16, wherein a thin, undoped semiconductor layer is deposited as the conductor layer.

18. The method of claim 17, wherein the semiconductor body comprises silicon, and an undoped silicon layer is deposited as the semiconductor layer.

19. The method of claim 16, wherein an amorphous silicon layer is deposited as the conductor layer, and the amorphous silicon layer is converted into an HSG layer in a region of the amorphous silicon layer not covered by the protective layer.

20. The method of claim 16, wherein an aluminum oxide layer is deposited as the protective layer by atomic layer deposition.

21. The method of claim 20, wherein the aluminum oxide layer is deposited with trimethylaluminum and water, and the aluminum oxide layer has a thickness of 5 nm to 10 nm.

22. The method of claim 21, wherein the aluminum oxide layer is subjected to heat treatment at 600° C. to 1200° C. for a time duration of 10 seconds to 100 seconds.

23. The method of claim 16, wherein, in step (d), the semiconductor body is etched in the lower trench region such that the diameter of the trench in the lower trench region is greater than the diameter of the trench in the upper trench region.

24. The method of claim 16, wherein the protective layer comprises aluminum oxide that is removed by etching with an acid.

25. The method of claim 16, wherein the buried plate formed by gas phase doping.

26. The method of claim 25, wherein the gas phase doping is performed at approximately 950° C. in an AsH₃ atmosphere.

27. The method of claim 16, wherein, in step (h), the dielectric layer is formed from at least one of silicon dioxide, silicon nitride, and aluminum oxide.

28. The method of claim 16, wherein the trench filling is deposited as doped polycrystalline silicon.

29. The method of claim 28, wherein the polycrystalline silicon is doped with arsenic.

30. The method of claim 16, wherein the dielectric layer is removed wet-chemically selectively with respect to the conductor layer.

31. The method of claim 16, wherein the conductor layer is removed selectively with respect to silicon dioxide and silicon nitride.
